(19) United States
(12) Patent Application Publication
(10) Pub. No.: US 2024/0328027 A1
(43) Pub. Date: Oct. 3, 2024

(54) CHAMBER COATING MATERIAL AND METHOD FOR MANUFACTURING THE SAME

(71) Applicant: GREEN RESOURCE CO., LTD., Incheon (KR)

(72) Inventors: Jong Beom LEE, Incheon (KR); Jong Soo LEE, Incheon (KR); Byounggook KWON, Incheon (KR)

(21) Appl. No.: 17/909,476

(22) PCT Filed: Mar. 11, 2020
(86) PCT No.: PCT/KR2020/003386

§ 371 Date: Sep. 6, 2022

(30) Foreign Application Priority Data
Mar. 6, 2020 (KR) 10-2020-0028372

(51) Int. Cl. C23C 14/08; C23C 14/02; C23C 14/10; C23C 14/24; C23C 14/58

(52) U.S. Cl. CPC C30B 1/023; C23C 14/022; C23C 14/081; C23C 14/083; C23C 14/10; C23C 14/24; H01J 37/32495

(57) ABSTRACT

A method for manufacturing a coating material formed on an inner surface of a chamber is provided. The method includes: i) providing a substrate including at least one material selected from the group consisting of SiC, SiO₂, and Al₂O₃; ii) providing a first coating portion including SiOₓ (0.1≤x≤2 as a molar ratio) or AlO_{y} (0.1≤y≤1.5 as a molar ratio) on the substrate; iii) providing a second coating portion including YO_{z} (0.1≤z≤1.5 as a molar ratio) on the first coating portion; iv) providing a laminate in which the first coating portion and the second coating portion are repeatedly stacked; and v) heating the laminate to provide a coating layer of a single crystalline layer by a solid-state reaction between the first coating portion and the second coating portion.

### TECHNICAL FIELD

The present invention relates to a chamber coating material and its manufacturing method. More specifically, the present invention relates to a chamber coating material having corrosion resistance even in plasma or a strong corrosive atmosphere, and a method for manufacturing the same.

### BACKGROUND ART

In recent years, due to the rapid development of the mobile industry, miniaturization and high integration of semiconductors and the like are more urgently required. Therefore, in order to highly integrate semiconductors, new technologies for stacking in 3D form are being developed, and in this case, a different process from the existing semiconductor process is required. That is, since it is necessary to form the device in an erected state, then quickly etch and remove a specific part in a short time, an etching gas or solution having strong corrosiveness is required.

By using such an etchant having strong acidity, the window or inner wall in the chamber for manufacturing the device is corroded. That is, as the inner surface of the chamber comes into contact with plasma in which a reactive halogen gas is injected or a strong acid etching atmosphere, resulting aggregates fall and contaminate the device being manufactured. Therefore, it is necessary to prepare a coating material capable of maintaining corrosion resistance even in plasma or a strongly acidic atmosphere in which reactive halogen gas is injected.

### DISCLOSURE

### Technical Problem

A coating material for a corrosion-resistant chamber for plasma or a strong corrosive atmosphere is provided. In addition, a method for manufacturing the aforementioned coating material is provided.

### Technical Solution

The method of manufacturing a coating material for a chamber according to an embodiment of the present invention includes: i) providing a substrate including at least one material selected from the group consisting of SiC, SiO₂, and Al₂O₃; ii) providing a first coating portion including SiOₓ (0.1≤x≤2 as a molar ratio) or AlO_{y} (0.1≤y≤1.5 as a molar ratio) on the substrate; iii) providing a second coating portion including YO_{z} (0.1≤z≤1.5 as a molar ratio) on the first coating portion; iv) providing a laminate in which the first coating portion and the second coating portion are repeatedly stacked; and v) heating the laminate to provide a coating layer of a single crystalline layer by a solid-state reaction between the first coating portion and the second coating portion.

The substrate may include the SiC in the providing the substrate. The first coating portion may include the SiOₓ (0.1≤x≤2 as a molar ratio) in the providing the first coating portion. The laminate may be heated at 1000° C. to 1500° C., and the coating layer may include at least one material selected from the group consisting of Y₂SiO₅ and Y₂Si₂O₇ in the providing the coating layer. The ratio of the thickness of the second coating portion to the thickness of the first coating portion may be 1.7 to 2 when the laminate may include Y₂SiO₅ in the providing the laminate. The ratio of the thickness of the second coating portion to the thickness of the first coating portion may be 0.8 to 1.25 when the laminate may include Y₂Si₂O₇ in the providing the laminate. The x may be 0.1 to 1 as a molar ratio in the providing the first coating portion, and the z may be 0.1 to 1 as a molar ratio in the providing the second coating portion.

The substrate may include the Al₂O₃ in the providing the substrate. The first coating portion may include the AlO_{y} (0.1≤y≤1.5 as a molar ratio) in the providing the first coating portion. The laminate may be heated at 1000° C. to 1500° C., and the coating layer may include Y_{α}Al_{β}O_{γ} (2.5≤α≤3.5, 4.5≤β≤5.5, 11.5≤γ≤12.5 as a molar ratio) in the providing the coating layer.

The substrate may include the Al₂O₃ in the providing the substrate. The first coating portion may include the AlO_{y} (0.1≤y≤1.5 as a molar ratio) in the providing the first coating portion. The laminate may be heated at 1000° C. to 1500° C., and the coating layer may include at least one compound selected from the group consisting of Y₃Al₅O₁₂, YAlO₄ and Y₄Al₂O₉ in the providing the coating layer. The ratio of the thickness of the second coating portion to the thickness of the first coating portion may be 0.8 to 1.2 when the coating layer includes Y₃Al₅O₁₂ in the providing the laminate. The ratio of the thickness of the second coating portion to the thickness of the first coating portion may be 1.3 to 1.8 when the coating layer includes YAlO₄ in the providing the laminate. The ratio of the thickness of the second coating portion to the thickness of the first coating portion may be 1.6 to 2.5 when the coating layer includes Y₄Al₂O₉ in the providing the laminate.

The y may be 0.1 to 1 in the providing the first coating portion, and the z may be 0.1 to 1 in the providing the second coating portion. The laminate may be heated to 800° C. to 1300° C., the thickness of the coating layer is smaller than the thickness of the laminate, and the ratio of the thickness of the laminate to the thickness of the coating layer may be 1.25 to 1.6 in the providing the coating layer. The first coating portion and the second coating portion may be repeatedly stacked 2 to 10 times in the providing the laminate.

The method of manufacturing a coating material for a chamber according to an embodiment of the present invention may further include treating a surface of the substrate between the providing the substrate and the providing the first coating portion. The surface treatment may be performed by plasma or an ion beam, and the surface roughness (Ra) of the substrate may be in a range from 0.1 μm to 0.3 μm. When the surface treatment is performed by the ion beam, the ion beam power may be 0.5 KW to 3 KW.

The coating material according to an embodiment of the present invention may be manufactured by the above-described methods.

### Advantageous Effects

A coating material for a chamber containing Y₂SiO₅ or YAG having corrosion resistance against plasma or a strong corrosive atmosphere can also be prepared. Therefore, it is possible to prevent contamination of the device due to the drop of foreign substances due to corrosion of the inner wall of the chamber.

### DESCRIPTION OF DRAWINGS

FIG. 1 is a schematic flowchart of a method for manufacturing a chamber coating material for manufacturing a device according to a first embodiment of the present invention.

FIG. 2 is a schematic graph showing a status when a surface of the substrate is treated by plasma or ion beam.

FIG. 3 is a graph in the case of treating the surface of a substrate with an ion beam.

FIGS. 4 to 7 are schematic cross-sectional views of the coating layer formed at each step of a method of manufacturing the chamber coating material.

FIG. 8 schematically shows a crystal structure and a chemical formula unit of a coating layer prepared by the method for manufacturing the chamber coating material of FIG. 1.

FIG. 9 is a scanning electron microscope photograph of the cross-section of the coating layer prepared before and after heating according to the first experimental example of the present invention.

FIG. 10 is an XRD graph of the coating material prepared according to the first experimental example of the present invention.

FIG. 11 is an XRD graph of each coating layer before heating the coating material prepared according to the second experimental example of the present invention.

FIG. 12 is a scanning electron microscope photograph of the cross-section of the coating material before and after heating according to the second experimental example of the present invention.

FIG. 13 is a schematic graph showing a process in which a plurality of coating layers are transformed into a single layer of coating material according to an increase in temperature in the second experimental example of the present invention.

FIG. 14 is an XRD graph of the coating material prepared according to the second experimental example of the present invention.

FIG. 15 is a graph showing the results of etching experiments according to Comparative Examples 1 to 3 and Experimental Examples 1 and 2.

### BEST MODE

The terminology used herein is for the purpose of referring to specific embodiments only, and is not intended to limit the invention. As used herein, the singular forms also include the plural forms unless the phrases clearly indicate the opposite. The meaning of “comprising,” as used herein, specifies a particular characteristic, region, integer, step, operation, element and/or component, and other specific characteristic, region, integer, step, operation, element, component, and/or group. It does not exclude the existence or addition of

Although not defined otherwise, all terms including technical and scientific terms used herein have the same meaning as commonly understood by those of ordinary skill in the art to which the present invention belongs. Commonly used terms defined in the dictionary are additionally interpreted as having a meaning consistent with the related art literature and the presently disclosed content, and unless defined, are not interpreted in an ideal or very formal meaning.

More specifically, the term “element” used hereinafter means “component included in electric or electronic device”. The component may be an OLED panel or a semiconductor, but is not limited thereto, and may be another object.

Hereinafter, exemplary embodiments of the present invention will be described in detail with reference to the accompanying drawings so that those skilled in the art to which the present invention pertains can easily practice it. However, the present invention can be implemented in many different forms and is not limited to the embodiments described herein.

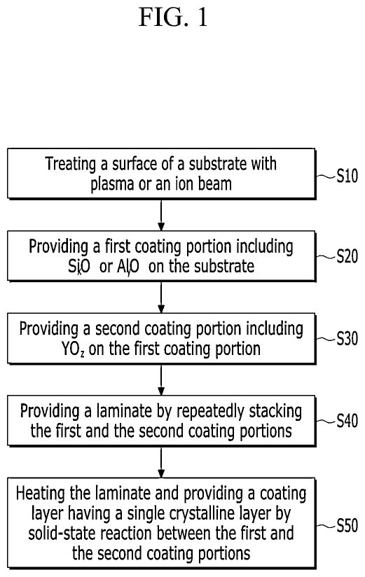

FIG. 1 schematically shows a flowchart of a method for manufacturing a chamber coating material according to an embodiment of the present invention. The method for manufacturing the chamber coating material of FIG. 1 is only for illustrating the present invention and the present invention is not limited thereto. Therefore, the method for manufacturing the chamber coating material can be modified to other forms.

As shown in FIG. 1, the method for manufacturing a chamber coating material includes treating a surface of a substrate with plasma or an ion beam S10, providing a first coating portion including SiOₓ or AlO_{y} on the substrate S20, providing a second coating portion including YO_{z} on the first coating portion S30, providing a laminate by repeatedly stacking the first and second coating portions S40, and heating the laminate and providing a coating layer having a single crystalline layer by solid-state reaction between the first and second coating portions S50. In addition, the method for manufacturing the coating material may further include other steps if necessary.

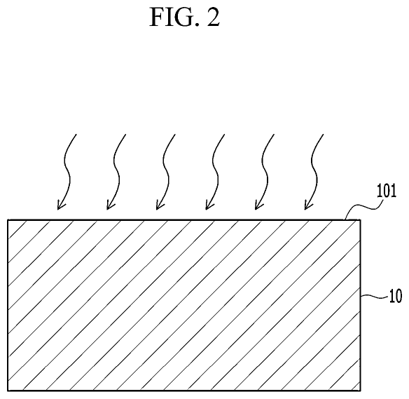

FIGS. 2 and 4 to 7 schematically show the cross-sectional structure of the coating layer prepared in each step of FIG. 1. The cross-sectional structures of FIGS. 2 and 4 to 7 are only for illustrating the present invention and the present invention is not limited thereto. Therefore, the cross-sectional structures shown in FIGS. 2 and 4 to 7 can be modified into other forms. Hereinafter, a method for manufacturing the chamber coating material will be described with reference to FIGS. 1 to 7.

As shown in FIG. 1, in step S10, a substrate 10 (FIG. 2, hereinafter referred to the same) is provided, and the surface thereof is treated with plasma or an ion beam. The substrate 10 may be an inner wall of the chamber for manufacturing the device. The device can be a semiconductor or a display. During a process for manufacturing the device, the substrate 10 may be corroded by direct contact with a corrosive atmosphere in the chamber, particularly plasma. Therefore, the surface of the substrate 10 is covered with a coating material having corrosion resistance to prevent the substrate 10 from directly contacting a corrosive atmosphere. As a substrate, SiC, SiO₂, or Al₂O₃ may be used. In addition, AlN, Al₂O₃—Y₂O₃, or the like can also be used.

As shown in FIG. 2, the surface 101 of the substrate 10 is treated to increase the adhesion of the coating layer to be attached thereon in a subsequent process. The surface can be treated with an ion beam or plasma. In particular, multiple coating layers are located over the substrate 10 in a subsequent process. Therefore, it is necessary to improve the adhesion of the substrate 10 and the layers to be stacked thereon. Therefore, the surface 101 of the substrate 10 is treated.

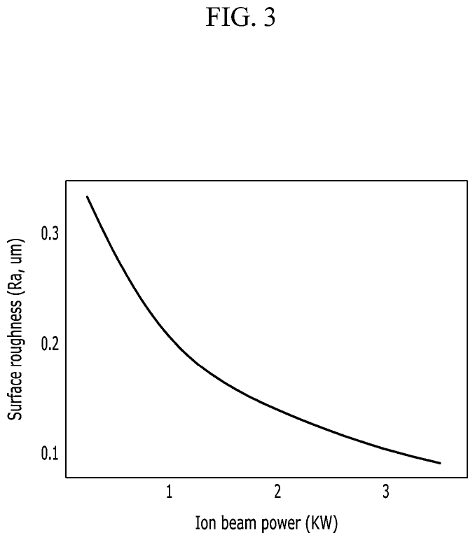

FIG. 3 shows a graph in the case of surface-treating the surface 101 of the substrate 10 with an ion beam. FIG. 3 is only for illustrating the present invention, and the present invention is not limited thereto. Therefore, the ion beam process of FIG. 3 may be modified into other forms.

As shown in FIG. 3, the surface 101 is subjected to ion beam treatment. The roughness of the surface 101 may be gradually lowered by gradually increasing the ion beam power. That is, the surface 101 is planarized by the ion beam treatment to lower the surface roughness. In addition, through cleaning and activation of the surface 101, adhesion between the coating layers to be attached to the surface 101 in a subsequent process and the surface 101 may be improved. Preferably, the ion beam power may be 0.5 KW to 3 KW. When the ion beam power is too low, a desired surface roughness cannot be obtained. In addition, when the ion beam power is too high, the energy consumption increases, thereby increasing the process cost. Therefore, the ion beam power is adjusted within the above-described range. To this end, the surface 101 may be irradiated with an ion beam for 5 to 60 minutes. As a result, the surface roughness Ra of the surface 101 may be 0.1 μm to 0.3 μm. When the surface roughness is too large, the surface 101 is not well planarized, so it may be difficult to laminate a plurality of coating layers in a subsequent process. In addition, when the surface roughness is too low, there is a problem in that the ion beam treatment time is long and the process cost increases. Therefore, it is preferable to maintain the surface roughness of the surface 101 in the above-mentioned range.

Meanwhile, the surface 101 may be treated with plasma. That is, the surface 101 is treated with plasma while the plasma collides with the surface 101 of the substrate 10. Plasma is an ionized gas and is composed of photons, ions, electrons, decomposed gas, and radicals. Therefore, the surface 101 is modified by physically and chemically reacting with the plasma. That is, the surface 101 is homogenized and its adhesion is improved when a coating layer is formed in a subsequent process.

Returning to FIG. 1, in the step S20 of FIG. 1, a first coating portion 20 is provided on the substrate 10 (shown in FIG. 3, hereinafter referred to the the same). The first coating portion 20 includes SiOₓ or AlO_{y}. Here, x may be 0.1 to 2 in a molar ratio. More preferably, x may be 0.1 to 1. In addition, in a molar ratio, y may be 0.1 to 1.5. More preferably, y may be 0.1 to 1. If the value of x or y is too high, a large amount of oxygen may be mixed, and the coating layer prepared in a subsequent process may be easily broken. Further, when the value of x or y is too low, it is difficult for silicon or aluminum to form a stable oxide. Therefore, it is desirable to keep the molar ratio within the above-mentioned range. The first coating portion 20 may be formed on the substrate 10 by physical vapor deposition. Therefore, since the first coating portion 20 can be formed by an in-situ process, process control is easy. On the other hand, when using thermal spraying, process control is difficult.

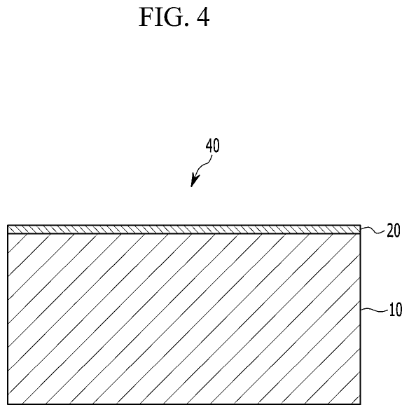

The thickness t20 (shown in FIG. 4) of the first coating portion 20 may be 0.4 μm to 1 μm. If the thickness t20 is too small, mutual diffusion with the second coating portion 30 provided in a subsequent process is not achieved well. In addition, if the thickness t20 is too large, the material cost is high and the process time becomes long. Therefore, it is preferable to keep the thickness t20 in the above-described range.

On the other hand, if the substrate 10 includes SiC, it is preferable that the first coating portion 20 includes the above-described SiOₓ. In this case, since both the substrate 10 and the first coating portion 20 contain Si, the first coating portion 20 is attached well on the substrate 10. As a result, the first coating portion 20 is not peeled off from the substrate 10 by thermal stress when the coating material prepared in the subsequent process is actually used.

If the substrate 10 includes Al₂O₃, it is preferable that the first coating portion 20 includes the above-described AlO_{y}. In this case, since both the substrate 10 and the first coating portion 20 include Al, the first coating portion 20 is attached well on the substrate 10. As a result, the first coating portion 20 is not peeled off from the substrate 10 by thermal stress when the coating material prepared in the subsequent process is actually used.

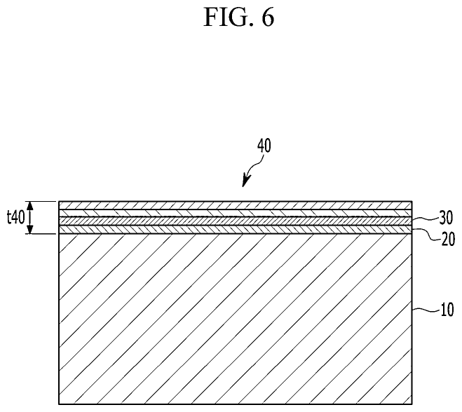

Next, in step S30, the second coating portion 30 is provided on the first coating portion 20 (shown in FIG. 6). The second coating portion 30 includes YO₂. Here, z may be 0.1 to 1.5. More preferably, z may be 0.1 to 1. If the value of z is too high, the coating layer may be hardened due to the incorporation of a large amount of oxygen. In addition, if the value of z is too small, there is a problem that yttrium is difficult to form as a stable oxide. Therefore, it is preferable to maintain z in the above-mentioned range. The second coating portion 30 may be formed in the same way as the first coating portion 20. For example, the second coating portion 30 is attached on the first coating portion 20 by evaporating yttria by a physical vapor deposition method. Yttria has excellent chemical and corrosion resistance. In particular, yttria has excellent plasma corrosion resistance. Therefore, it is suitable to protect the substrate from plasma generated in the chamber.

Meanwhile, the thickness t30 of the second coating portion 30 may be 0.5 μm to 2.5 μm. If the thickness t30 is too small, mutual diffusion with the first coating portion 20 is not performed well. In addition, if the thickness t30 is too large, the material cost is high and the process time becomes long. Therefore, it is preferable to keep the thickness t30 in the above-described range.

Next, in step S40 of FIG. 1, the first and second coating portions 20 and 30 are repeatedly stacked to provide a laminate 40. FIG. 6 shows a state in which the first and second coating portions 20 and 30 are repeatedly stacked four times on the substrate 10 as an example. The first and second coating portions 20 and 30 may be stacked repeatedly 2 to 10 times. The difference in thermal expansion coefficient between the substrate and the laminate 40 can be reduced by repeated stacking.

If the stacking of the first and second coating portions 20 and 30 is not repeated, the diffusion between the first and second coating portions 20 and 30 does not easily occur when heated in a subsequent process, and thus uniform coating layer is difficult to be manufactured. Furthermore, if a single layer in which the materials of the first and second coating portions 20 and 30 are mixed is formed without being stacked, the thickness thereof is too thin, and thus corrosion resistance to plasma may be deteriorated. In addition, the materials of the first and second coating portions 20 and 30 cannot be uniformly mixed, thereby the characteristics thereof may be lowered. Therefore, it is preferable to repeatedly stack the first and second coating portions 20 and 30 two or more times. In addition, if the number of times of the stacking of the first and second coating portions 20 and 30 is too many, the manufacturing process time of the coating material is lengthened and the unit cost is increased by using a large amount of material. Therefore, it is preferable to stack the first and second coating portions 20 and 30 within the above-described number of times.

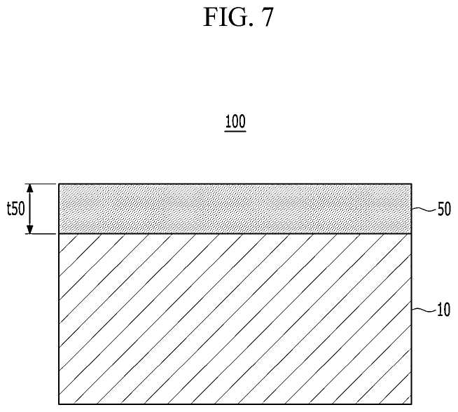

In addition, in step S50 of FIG. 1, the laminate 40 is heat-treated to provide a coating layer 50, thereby forming a coating material 100 including the substrate 10 (shown in FIG. 7). First, if the first coating portion 20 includes the aforementioned SiOₓ, the coating layer 50 is formed to contain Y₂SiO₅ or Y₂Si₂O₇ by reaction of SiOₓ and YO_{z}. This can control the molar ratio of the Y—Si—O-based compound by adjusting the thickness t20 of the first coating portion 20 and the thickness t30 of the second coating portion 30 in FIG. 4. For example, if the laminate 40 includes Y₂SiO₅, the ratio of the thickness t30 of the second coating portion 30 to the thickness t20 of the first coating portion 20 may be 1.7 to 2. If the ratio is lower or higher than this, Y₂SiO₅ is not formed, so the ratio is adjusted to the above-mentioned range. On the other hand, if the laminate 40 includes Y₂Si₂O₇, the ratio of the thickness t30 of the second coating portion 30 to the thickness t20 of the first coating portion 20 is 1:1.3 to 1:0.8. If the ratio is lower or higher than this, Y₂Si₂O₇ is not formed, so the ratio is adjusted to the above-mentioned range.

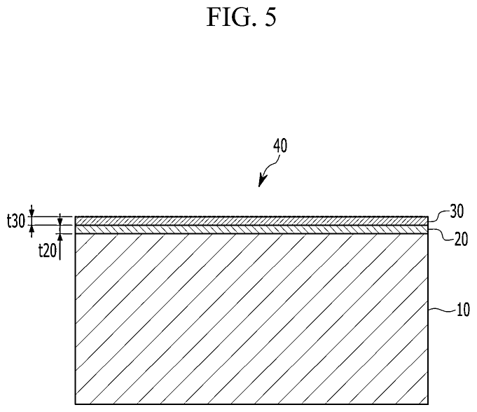

In addition, if the first coating portion 20 includes the above-described AlO_{y}, the coating layer 50 is formed to include Y₃Al₅O₁₂, YAlO₄, or Y₄Al₂O₉ by the reaction of AlO_{y} and YO_{z}. This may control the molar ratio of the Y—Al—O-based compound by adjusting the thickness t20 of the first coating portion 20 and the thickness t30 of the second coating portion 30 in FIG. 5. Adhesion at the interface between the first and second coating portions 20 and 30 may be improved by heat treatment.

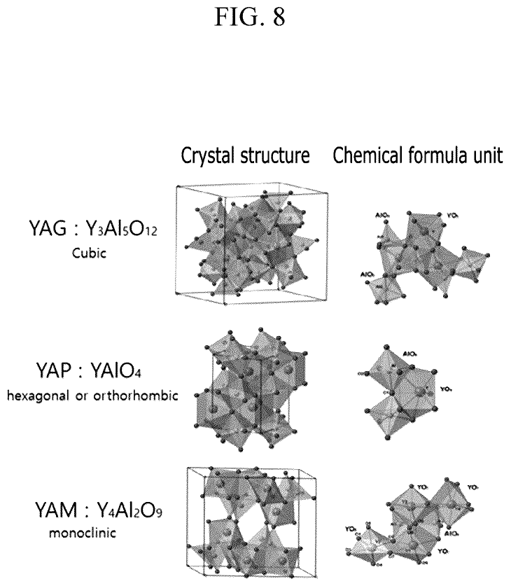

FIG. 8 shows a crystal structure and chemical unit of the Y—Al—O-based coating layer prepared in this way. Various Y—Al—O-based coating layers such as YAG, YAP, or YAM are prepared by adjusting the thickness t20 of the first coating portion 20 and the thickness t30 of the second coating portion 30 shown in FIG. 5. YAG is a cubic system with the chemical formula Y₃Al₅O₁₂, YAP is a hexagonal or tetragonal system with the chemical formula YAlO₄, and YAM is a monoclinic system with the chemical formula Y₄Al₂O₉. YAP and YAM can be formed according to process conditions.

If the ratio of the thickness t30 of the second coating portion 30 to the thickness t20 of the first coating portion 20 is 0.8 to 1.2, a coating layer 50 including Y₃Al₅O₁₂ may be prepared. If the ratio is lower or higher than this, Y₃Al₅O₁₂ is not formed, so the ratio is adjusted to the above-mentioned range. In addition, if the ratio of the thickness t30 of the second coating portion 30 to the thickness t20 of the first coating portion 20 is 1.3 to 1.8, a coating layer 50 including YAlO₄ may be prepared. If the ratio is lower or higher than this, YAlO₄ is not formed, so the ratio is adjusted to the above-mentioned range. In addition, if the ratio of the thickness t30 of the second coating portion 30 to the thickness t20 of the first coating portion 20 is 1.6 to 2.5, a coating layer 50 including Y₄Al₂O₉ may be manufactured. If the ratio is lower or higher than this, Y₄Al₂O₉ is not formed, so the ratio is adjusted to the above-mentioned range.

In order to form a single-layer coating layer 50, the laminate 40 (shown in FIG. 5, hereinafter referred to the same) may be heated at 800° C. to 1500° C. for 30 minutes to 5 hours. In this case, the single layer is formed to be crystalline. Given the temperature range and temperature time, no amorphous material is formed that may be susceptible to corrosion. If the heating temperature of the laminate 40 is too high, the laminate 40 may be overheated. In addition, if the heating temperature of the laminate 40 is too low, it is not easy for the first coating portion 20 and the second coating portion 30 to be mutually united and form a compound. Therefore, it is preferable to heat the laminate 40 in the above-described temperature range. If the heating time is too short, the coating layer 50 is insufficiently formed. In addition, if the heating time is too long, the coating layer 50 may be deteriorated. Therefore, it is preferable to adjust the heating time in the above-described range.

Returning to FIG. 7, if the laminate 40 is heated through the above-described method, the thickness t50 of the coating layer 50 is smaller than the thickness t40 of the laminate 40. That is, if the laminate 40 is heated to the above-described temperature range, the laminate 40 is contracted to some extent to form a coating layer 50 with a reduced thickness. In this case, a ratio of the thickness t50 of the coating layer 50 to the thickness t40 of the laminate 40 may be 1.1:1 to 1.6:1. If this ratio is too small, the heat treatment time is insufficient, and the components included in the laminate 40 are not evenly mixed and the coating layer 50 is not formed as a single layer. In addition, if this ratio is too large, the laminate 40 may be overheated and cracks may occur. Therefore, it is desirable to keep the ratio in the above-described range. Here, the thickness t50 of the coating layer 50 may be 0.5 μm to 3 μm.

Unlike the exemplary embodiment of the present invention, if the coating layer 50 is formed as a plurality of layers instead of a single layer, the process is complicated, and thermal stress occurs between each layer having different materials and cracks are generated. This is the same in the coating material with a plurality of layers which is generated due to insufficient heat treatment instead of a single layer. On the contrary, in the embodiment of the present invention, since the coating layer 50 having a single layer is finally manufactured, the process is not only simple, but also has excellent plasma corrosion resistance. That is, after laminating a plurality of coating layers 20 and 30, a mutual diffusion reaction therebetween is induced by heat treatment, so that a coating layer 50 having excellent properties can be manufactured.

Hereinafter, the present invention will be described in more detail through experimental examples. These experimental examples are only for illustrating the present invention. The present invention is not limited to this.

### Experimental Example 1

A coating layer was formed on the substrate of SiC using the method of FIG. 1. First, the surface of the substrate was plasma treated under 5 KW power conditions. Then, the SiO₂ layer and the Y₂O₃ layer were repeatedly stacked by physical vapor deposition alternating the silicon source with a coating rate of 3.0 Pa/sec and an oxygen flow of 10 sccm and an yttrium source of 1.5 Pa/sec and a flow rate of 5 sccm of oxygen. Here, the SiO₂ layer and the Y₂O₃ layer were repeated 4 times to prepare a laminate having a total of 8 layers. Then, the laminate was heated at a temperature of 800° C. to 1300° C. for 180 minutes in an oxygen atmosphere to prepare a coating material. In order to test the prepared coating material, an etching experiment was performed with a volume ratio of CF₄:O₂ of 95:5 in accordance with a use environment.

### Experimental Example 2

A coating layer was formed on the substrate of Al₂O₃ using the method of FIG. 1. First, the surface of the substrate was plasma treated under 5 KW power conditions. Then, the Al₂O₃ layer and the Y₂O₃ layer were repeatedly stacked by physical vapor deposition alternating the aluminum source with a coating rate of 3.0 Pa/sec and an oxygen flow of 10 sccm and an yttrium source with a coating rate of 1.5 Pa/sec and an oxygen flow of 5 sccm. Here, the Al₂O₃ layer and the Y₂O₃ layer were alternated twice to prepare a laminate having a total of 4 layers. Then, the coating material was prepared by heating the laminate for 300 minutes at 1000° C. to 1400° C. in an oxygen atmosphere. In order to test the prepared coating material, an etching experiment was performed with a volume ratio of CF₄:O₂ of 95:5 in accordance with a use environment.

### Comparative Example 1

Al₂O₃ bulk material mainly used as a substrate was prepared. An etching experiment was performed by setting the volume ratio of CF₄:O₂ of 95:5 to Al₂O₃ bulk material.

### Comparative Example 2

On the substrate made of alumina, Y₂O₃ coating material was formed using an APS (atmospheric plasma spray) process. The rest of the processes except the APS process were the same as the Experimental Example 1 described above or followed the general APS test conditions. The Y₂O₃ coating material was subjected to an etching experiment with CF₄:O₂ volume ratio of 95:5.

### Comparative Example 3

Y₂O₃ coating was formed on the alumina substrate through physical vapor deposition. The rest of the processes were the same as Experimental Example 1 described above. The Y₂O₃ coating material was subjected to an etching experiment with a CF₄:O₂ volume ratio of 95:5.

### Experiment Result

### Coating Structure Observation

### Experimental Results of the Experimental Example 1

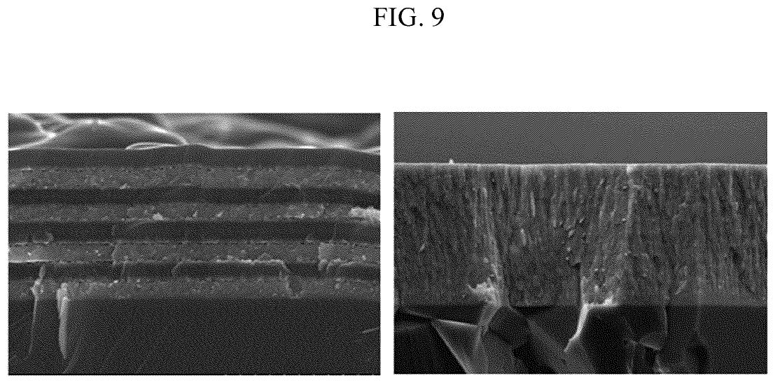

FIG. 9 shows a scanning electron microscope photograph of the cross-section of the coating material prepared before and after heating according to the first experimental example of the present invention. That is, the left side of FIG. 9 shows a scanning electron microscope photograph of the cross section of the coating material before heating, while the right side of FIG. 9 shows a scanning electron microscope photograph of the cross section of the coating material after heating.

As shown in the photo on the left of FIG. 9, when a laminate is prepared by a physical vapor deposition method, it can be seen that total 8 layers of SiO₂ and Y₂O₃ are repeatedly formed. As a result of heating the laminate, as shown in the right photo of FIG. 9, it was confirmed that a single layer of Y₂SiO₅ (YSO) was formed by nucleation and recrystallization by mutual diffusion of the SiO₂ layer and the Y₂O₃ layer.

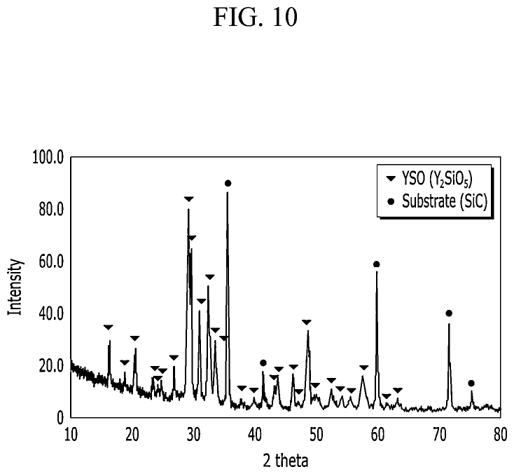

FIG. 10 shows an XRD graph of the coating material prepared according to the first experimental example of the present invention. As shown in FIG. 10, as a result of XRD experiment, Y₂SiO₅ and SiC were detected in the coating material. Here, it was confirmed that SiC is a component of the substrate, while Y₂SiO₅ is a component of the coating layer. Therefore, it is confirmed that the coating layer of Y₂SiO₅ is formed well through the above-described methods.

### Experimental Results of the Experimental Example 2

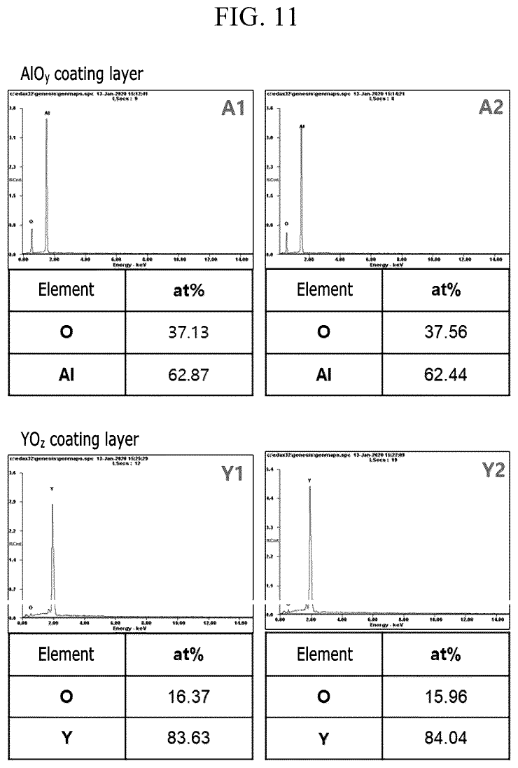

FIG. 11 shows an XRD graph of each coating layer before heating the coating material prepared according to the Experimental Example 2. Here, A means an AlO_{y} coating layer while Y means a Y₂O_{z} coating layer.

As shown in FIG. 11, the coating layers are sequentially stacked in the order of A1→Y1→A2→Y2. Here, at % of Al and O of the AlO_{y} coating layer and at % of Y and O of the YO_{z} coating layer are shown in a table. The ratio of Al and Y to O is within the aforementioned range. Depending on the experimental state, the fraction between Al and O and the fraction between Y and O may be slightly changed.

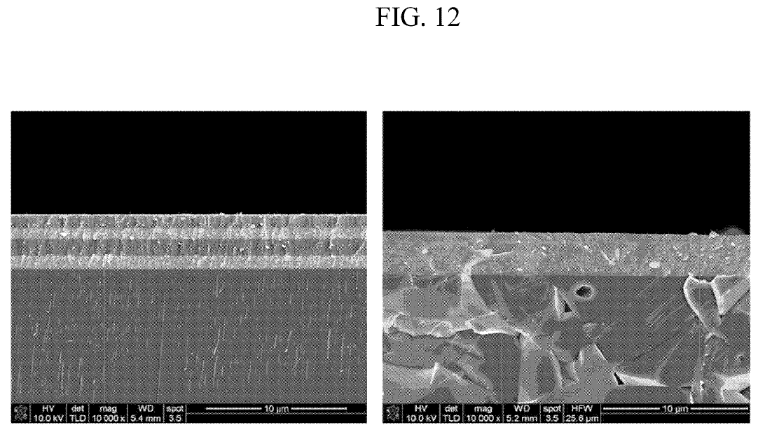

FIG. 12 shows a scanning electron microscope photograph of the cross-section of the coating material prepared before and after heating according to the second experimental example of the present invention. That is, the left side of FIG. 12 shows a scanning electron microscope photograph of the cross section of the coating material before heating, while the right side of FIG. 12 shows a scanning electron microscope photograph of the cross section of the coating material after heating.

As shown in the photo on the left side of FIG. 12, when a laminate is prepared by a physical vapor deposition method, it can be seen that a total of four layers of Al₂O₃ and Y₂O₃ are repeatedly formed. As a result of heating the laminate, as shown in the right picture of FIG. 12, it was confirmed that a single layer of Y₃Al₅O₁₂ (YAG) was formed by nucleation and recrystallization by mutual diffusion of the Al₂O₃ layer and the Y₂O₃ layer.

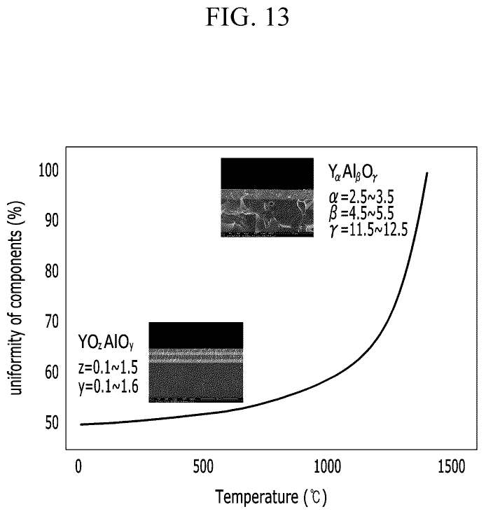

FIG. 13 is a graph schematically showing a process in which coating layers forming a laminate is transformed into the coating material of a single layer according to an increase in temperature in the second experimental example of the present invention

As shown in FIG. 13, a single layer of Y_{α}Al_{β}O_{γ} (2.5≤α≤3.5, 4.5≤β≤5.5, 11.5≤γ≤12.5) is formed as mutual diffusion occurs between the YO_{z} coating layers and the AlO_{y} coating layers stacked with each other in accordance with the increase of temperature. That is, the YO_{z} coating layer and the AlO_{y} coating layer are formed of a uniform material as the heat treatment temperature increases.

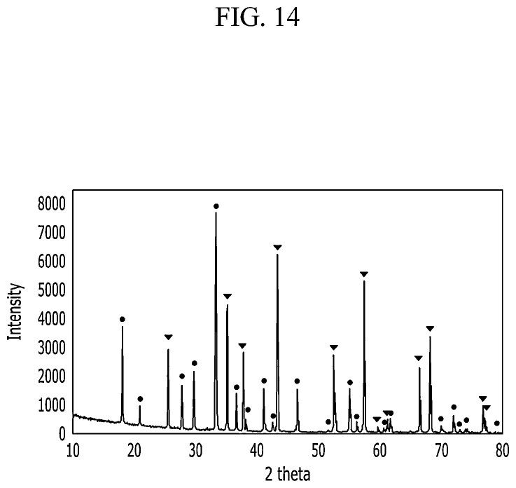

FIG. 14 shows an XRD graph of the coating material prepared according to the second experimental example of the present invention. As shown in FIG. 14, as a result of XRD experiments, Y₃Al₅O₁₂ and Al₂O₃ were detected in the coating material. Here, it was confirmed that Al₂O₃ is a component of the substrate, and Y₃Al₅O₁₂ is a component of the coating layer. Therefore, it was confirmed that the coating layer of Y₃Al₅O₁₂ was formed well through the above methods.

### Etching Experiment Results

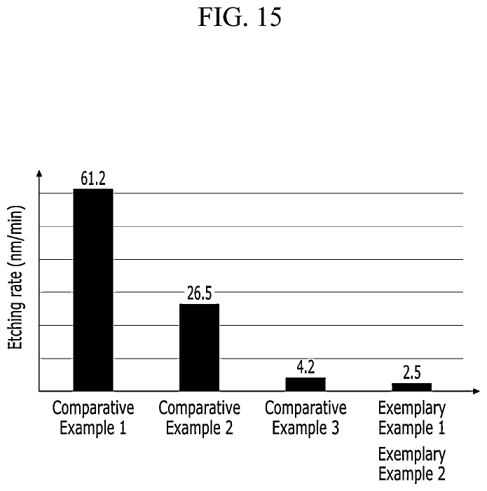

FIG. 15 shows a graph of the etching test results according to Comparative Examples 1 to 3, Experimental Examples 1 and 2.

As shown in FIG. 15, as a result of performing an etching experiment, it was confirmed that the etching rate of the coating material was only 2.5 nm/min in Experimental Example 1 and Experimental Example 2 of the present invention. On the contrary, in the Comparative Examples 1 to 3, the etch rates were much larger than those of Experimental Examples 1 and 2 described above. For example, the etch rates were 61.2 nm/min for Comparative Example 1, 26.5 nm/min for Comparative Example 2, and 4.2 nm/min for Comparative Example 3. Therefore, it was confirmed that the coating materials prepared through Experimental Example 1 and Experimental Example 2 of the present invention described above has excellent etching rates and are suitable for use in a plasma corrosion environment.

Although the present invention has been described as described above, those skilled in the art to which the present invention pertains will readily appreciate that various modifications and variations are possible without departing from the concept and scope of the claims set forth below.

### REFERENCE NUMERALS

10. substrate
101. surface
20. first coating portion
30. second coating portion
40. laminate
50. coating layer
100, 200. coating material

1. A method for manufacturing a coating material formed on an inner surface of a chamber, the method comprising:
providing a substrate comprising at least one material selected from the group consisting of SiC, SiO₂, and Al₂O₃;
providing a first coating portion comprising SiOₓ (0.1≤x≤2 as a molar ratio) or AlO_{y} (0.1≤y≤1.5 as a molar ratio) on the substrate;
providing a second coating portion comprising YO₂ (0.1≤z≤1.5 as a molar ratio) on the first coating portion;
providing a laminate in which the first coating portion and the second coating portion are repeatedly stacked; and
heating the laminate to provide a coating layer of a single crystalline layer by a solid-state reaction between the first coating portion and the second coating portion.

2. The method of claim 1, wherein the substrate comprises the SiC in the providing the substrate,
the first coating portion comprises the SiOₓ (0.1≤x≤2 as a molar ratio) in the providing the first coating portion, and
the laminate is heated at 1000° C. to 1500° C., and
the coating layer comprises at least one material selected from the group consisting of Y₂SiO₅ and Y₂Si₂O₇ in the providing the coating layer.

3. The method of claim 2, wherein a ratio of the thickness of the second coating portion to the thickness of the first coating portion is 1.7 to 2 when the laminate comprises Y₂SiO₅ in the providing the laminate.

4. The method of claim 2, wherein a ratio of the thickness of the second coating portion to the thickness of the first coating portion is 0.8 to 1.25 when the laminate comprises Y₂Si₂O₇ in the providing the laminate.

5. The method of claim 2, wherein the x is 0.1 to 1 as a molar ratio in the providing the first coating portion, and
the z is 0.1 to 1 as a molar ratio in the providing the second coating portion.

6. The method of claim 1, wherein the substrate comprises the Al₂O₃ in the providing the substrate,
the first coating portion comprises the AlO_{y} (0.1≤y≤1.5 as a molar ratio) in the providing the first coating portion,
the laminate is heated at 1000° C. to 1500° C., and
the coating layer comprises Y_{α}Al_{β}O_{γ} (2.5≤α≤3.5, 4.5≤β≤5.5, 11.5≤γ≤12.5 as a molar ratio) in the providing the coating layer.

7. The method of claim 1, wherein the substrate comprises the Al₂O₃ in the providing the substrate,
the first coating portion comprises the AlO_{y} (0.1≤y≤1.5 as a molar ratio) in the providing the first coating portion,
the laminate is heated at 1000° C. to 1500° C., and
the coating layer comprises at least one compound selected from the group consisting of Y₃Al₅O₁₂, YAlO₄, and Y₄Al₂O₉ in the providing the coating layer.

8. The method of claim 7, wherein a ratio of the thickness of the second coating portion to the thickness of the first coating portion is 0.8 to 1.2 when the coating layer comprises Y₃Al₅O₁₂ in the providing the laminate.

9. The method of claim 7, wherein a ratio of the thickness of the second coating portion to the thickness of the first coating portion is 1.3 to 1.8 when the coating layer comprises YAlO₄ in the providing the laminate.

10. The method of claim 7, wherein the ratio of the thickness of the second coating portion to the thickness of the first coating portion is 1.6 to 2.5 when the coating layer comprises Y₄Al₂O₉ in the providing the laminate.

11. The method of claim 2, wherein the y is 0.1 to 1 in the providing the first coating portion, and
the z is 0.1 to 1 in the providing the second coating portion.

12. The method of claim 1, wherein the laminate is heated to 800° C. to 1300° C., the thickness of the coating layer is smaller than the thickness of the laminate, and a ratio of the thickness of the laminate to the thickness of the coating layer is 1.25 to 1.6 In the providing the coating layer.

13. The method of claim 1, wherein the first coating portion and the second coating portion are repeatedly stacked 2 to 10 times in the providing the laminate.

14. The method of claim 1 further comprising treating surface of the substrate between the providing a substrate and the providing a first coating portion and
the surface treatment is performed by plasma or ion beam and the surface roughness (Ra) of the substrate is in a range from 0.1 μm to 0.3 μm.

15. The method of claim 14, wherein a power of the ion beam is 0.5 KW to 3 KW when the surface treatment is performed by the ion beam.

16. (canceled)
